(19) United States
(12) Patent Application Publication
(10) Pub. No.: US 2010/0281978 A1
(43) Pub. Date: Nov. 11, 2010

(54) INERTIAL SENSOR AND PRODUCING METHOD THEREOF

(75) Inventor: Pin Chang, Hsin Chu Hsien (TW)

Correspondence Address: VENABLE LLP, P.O. BOX 34385, WASHINGTON, DC, 20043-9998, US

(73) Assignee: Industrial Technology Research Institute, Hsinchu (TW)

(21) Appl. No.: 11/964,550

(22) Filed: Dec. 26, 2007

(30) Foreign Application Priority Data
Apr. 26, 2007 (TW) 96114793

(51) Int. Cl. G01P 15/08; G01R 3/00; H04R 17/00

(52) U.S. Cl. 73/514.11; 29/595; 29/25.35

(57) ABSTRACT

The present invention provides an inertial sensor and a producing method thereof. The inertial sensor measures the acceleration and angular acceleration of a moving object according to the sensed pressure difference (pressure gradient). The inertial sensor comprises a substrate; a circuit disposed on the substrate; a pressure device comprising an annular chamber that has a first end and a second end; a channel having a first end and a second end, with the second end being connected to the second end of the annular chamber; a pressure meter connected respectively to the first end of the annular chamber and the first end of the channel, wherein the pressure meter is electrically connected to the circuit; and a liquid filling the annular chamber. Hence, the present invention provides a highly sensitive planar inertial sensor, which simplifies the structure, makes easy the manufacturing process, and lowers the costs. The inertial sensor based on this invention can measure the acceleration and angular acceleration of a moving or rotating object, further allowing multi-axis measurements as a result of mutual integrations.

### FIELD OF THE INVENTION

This invention relates to an inertial sensor and producing method thereof;, and more particularly, a planar inertial sensor with improved sensitivity and a producing method for such an inertial sensor.

### BACKGROUND OF THE INVENTION

The inertial sensors disclosed in the prior arts are primarily applied to an accelerometer or a micro accelerometer. Four exemplary embodiments are presented as follows:

For example, the single unit position sensor disclosed in the U.S. Pat. No. 6,713,829 is used to produce a mass unit to be connected to a silicon substrate via an elastic structure and to make a capacitor. The acceleration can be calculated according to the elasticity coefficient of the elastic structure when the acceleration is generated through the moving of the mass unit.

Besides, the convection current responsive instrument disclosed in the U.S. Pat. No. 2,440,189 is used to produce a gas chamber. A heating element is provided inside the gas chamber to heat the gas therein, so as to change the gas density in the chamber. A temperature distribution can be detected as a result of a change in the acceleration, due to the effect of buoyancy. Acceleration can further be calculated by using a resistance bridge to read the temperature difference of a heating wire.

In addition, the thermal bubble type micro inertial sensor disclosed in the U.S. Pat. No. 7,069,785 is used to produce a liquid chamber. A heating element is provided inside the liquid chamber to heat the liquid therein, so as to form a bubble by partially gasifying the liquid. A temperature distribution can be detected as a result of a change in the location of the bubble due to the change of the acceleration. Acceleration can be calculated as a result.

Moreover, the accelerometer disclosed in the U.S. Pat. No. 2,650,991 is used to produce a liquid chamber whose wall is provided with a pressure sensing element for sensing an average pressure of the liquid inertia, so that the acceleration can be calculated. This patent is used to calculate the acceleration through the measurement of the average (total) pressure. Actually, the average pressure of the liquid in the sealed container is not necessarily in direct relation to the acceleration.

Finally, the liquid filled accelerometer disclosed in the U.S. Pat. No. 2,728,868 is used to produce a liquid chamber in which a pressure-sensing element is mounted on the chamber wall. This patent reveals both the acceleration and the reactive force exerted by the liquid on the chamber wall. It is the reactive force that is measured by the pressure-sensing element. This patent does not reveal the sensing of pressure gradient.

### SUMMARY OF THE INVENTION

The objective of the present invention is to provide a planar inertial sensor with high sensitivity. Namely, the invention relates to an inertial sensor and its producing method for the measurement of the angular acceleration of a rotating object by means of the pressure difference (the pressure gradient).

Another objective of the present invention is to provide a low-cost inertial sensor and producing method thereof.

In order to achieve the abovementioned objectives, the inertial sensor disclosed in one embodiment comprises: (1) a substrate; (2) a circuit disposed on the substrate; (3) a pressure device having an annular chamber that has a first end and a second end; (4) a channel having a first end and a second end, with the second end being connected to the second end of the annular chamber; (5) a pressure meter connected respectively to the first end of the annular chamber and the first end of the channel and electrically connected to the circuit; and (6) a fluid filling the annular chamber. Therefore, the present invention can achieve advantages of simple structure, easy manufacturing, and low costs.

The substrate can be a silicon wafer, an integrated circuit, a printed circuit board, a glass substrate, a plastic substrate, or a ceramic substrate.

The pressure meter can be a capacitive-type, a piezoelectric-type,or a piezoresistive-type pressure meter.

The fluid can be water, oil, liquid crystal, or their mixtures.

The inertial sensor further comprises an angular acceleration sensitivity obtained through the pressure difference between the pressure meter and the reference pressure. The angular acceleration is determined by applying the formula below:

α=P/(2πdR²); wherein
P stands for the pressure value of the pressure meter;
d stands for the fluid density;
α stands for the angular acceleration; and
R stands for the radius of the annular chamber.

The present invention provides another embodiment of the inertial sensor, which utilizes the pressure difference (pressure gradient) to measure an angular acceleration of a rotating object. The inertial sensor comprises: (1) a substrate; (2) a circuit disposed on the substrate; (3) a pressure device comprising an annular chamber that has a first end and a second end; (4) a base containing a channel that has a first end and a second end; (5) a first pressure meter connected respectively to the first end of the annular chamber and the first end of the channel and electrically connected to the circuit; (6) a second pressure meter connected respectively to the second end of the annular chamber and the second end of the channel and electrically connected to the circuit; and (7) a fluid filling the annular chamber.

The substrate can be a silicon wafer, an integrated circuit, a printed circuit board, a glass substrate, or a ceramic substrate.

The channel can be disposed on the substrate or be extended into the substrate. The channel also can be filled with air or be under vacuum condition. Moreover, the channel can be sealed off or be communicated to the outside world.

The first pressure meter and the second pressure meter can be a capacitive-type, a piezoelectric-type, or a piezoresistive-type pressure meter.

The fluid can be water, oil, liquid crystal, or their mixtures.

The inertial sensor further comprises an angular acceleration sensitivity obtained through the pressure difference between the first pressure meter and the second pressure meter. The angular acceleration is determined by applying the formula below:

α=(P₂−P₁)/(2πdR²); wherein
P₁ stands for the pressure value of the first pressure meter;
P₂ stands for the pressure value of the second pressure meter;
d stands for the fluid density;
α stands for the angular acceleration; and
R stands for the radius of the annular chamber.

The present invention provides yet another embodiment of the inertial sensor. The only difference between this embodiment and the second embodiment is that the channel designated for this embodiment can be extended into the substrate. The arrangement of the remaining elements of this embodiment is identical with that of the second embodiment.

The embodiment of the inertial sensor according to the present invention shows an inertial sensor utilizing the pressure difference (pressure gradient) to measure the acceleration of an object. The inertial sensor comprises: (1) a circuit; (2) a pressure device comprising a base that contains a channel, which has a first end and a second end; (3) a first pressure meter connected to the first end of the channel and electrically connected to the circuit; (4) a second pressure meter connected to the second end of the channel and electrically connected to the circuit; (5) a housing containing the pressure device; and (6) a fluid filling the housing.

The housing comprises a substrate disposed on the bottom of the housing, whereas the circuit and the pressure device are disposed on the substrate.

The channel further comprises a third end, and takes an L-shaped form on the planar surface; the pressure device further comprises a third pressure meter connected to the third end of the channel and electrically connected to the circuit.

The substrate can be a silicon wafer, an integrated circuit, a printed circuit board, a glass substrate, a plastic substrate, or a ceramic substrate.

The channel can be disposed on the substrate or be extended to the substrate. The channel also can be filled with air or be under vacuum condition. Moreover, the channel can be sealed off or be communicated to the outside world.

The first pressure meter, the second pressure meter, and the third pressure meter can be a capacitive-type, a piezoelectric-type, or a piezoresistive-type pressure meter.

The fluid can be water, oil, liquid crystal, or their mixtures.

The inertial sensor further comprises a linear acceleration sensitivity obtained through the pressure difference between the first pressure meter and the second pressure meter. The linear acceleration is determined by applying the formula below:

a=(P₂−P₁)/(d×S); wherein
P₁ stands for the pressure value of the first pressure meter;
P₂ stands for the pressure value of the second pressure meter;
d stands for the fluid density;
a stands for the acceleration; and
S stands for the distance between the center of the first pressure meter and the center of the second pressure meter.

A producing method for the inertial sensor according to the present invention, comprising the steps of (1) providing a housing; (2) forming a circuit within the housing; (3) forming a pressure device inside the housing, and (4) filling a fluid into the housing. Therefore, by utilizing a micro-structure manufacturing method to produce the inertial sensor, the present invention can reduce the size of the inertial sensor and enhance product applications.

The housing comprises a substrate disposed on the bottom of the housing, whereas the circuit and the pressure device are disposed on the substrate.

The substrate can be a silicon wafer, an integrated circuit, printed circuit board, a glass substrate, a plastic substrate, or a ceramic substrate.

The pressure device comprises: (1) a base containing a channel that has a first end and a second end; (2) a first pressure meter connected to the first end of the channel and electrically connected to the circuit; and (3) a second pressure meter connected to the second end of the channel and electrically connected to the circuit.

The channel further comprises a third end, and takes an L-shaped form on the planar surface; the pressure device further comprises a third pressure meter connected to the third end of the channel and electrically connected to the circuit.

The channel can be disposed on the substrate or be extended into the substrate. The channel also can be filled with air or be under vacuum condition. Moreover, the channel can be sealed off or be communicated to the outside world.

The first pressure meter, the second pressure meter, and the third pressure meter can be a capacitive-type, a piezoelectric-type, or a piezoresistive-type pressure meter.

The fluid can be water, oil, liquid crystal, or their mixtures.

In yet another embodiment of the inertial sensor, the present invention relates to an inertial sensor utilizing the pressure difference (pressure gradient) to measure the acceleration of a moving object. The inertial sensor comprises: (1) a circuit; (2) a pressure device comprising a base that contains a channel, which has a first end and a second end; (3) a first pressure meter connected to the first end of the channel and electrically connected to the circuit; (4) a second pressure meter connected to the second end of the channel and electrically connected to the circuit; and (5) a fluid filling the channel.

Both the present and the preceding embodiments can take the substrate channel as a housing for filling the fluid, wherein the outer pressure can be provided as a reference pressure, so as to make the structure less complicated. Since the formation of the fluid's inner pressure gradient has nothing to do with the shape of the housing, the design of the channel will suffice provided that it allows free communication of the fluid.

The present invention utilizes a micro-structure manufacturing method to produce the inertial sensor—namely, an inertial sensor that utilizes the pressure difference to measure the acceleration or angular acceleration of a moving or rotating object. The present invention provides a planar inertial sensor with high sensitivity, which offers a simple structure and an undemanding manufacturing process, allows measurements of the acceleration or angular acceleration of a moving or rotating object, and further undertakes multi-axis measurements through mutual integration.

### BRIEF DESCRIPTION OF THE DRAWINGS

FIG. 1 is a front-view cross-sectional diagram of an inertial sensor according to the first embodiment of the present invention.

FIG. 2 is a top-view diagram of the inertial sensor according to the first embodiment of the present invention.

FIG. 3 is a structure of a pressure meter of the inertial sensor according to the present invention.

FIG. 4 is another structure of the pressure meter of the inertial sensor according to the present invention.

FIG. 5 is yet another structure of the pressure meter of the inertial sensor according to the present invention.

FIG. 6 is a front-view cross-sectional diagram of the inertial sensor according to the second embodiment of the present invention.

FIG. 7 is a top-view diagram of the inertial sensor according to the second embodiment of the present invention.

FIG. 8 is a front-view cross-sectional diagram of the inertial sensor according to the third embodiment of the present invention.

FIG. 9 is a front-view cross-sectional diagram of the inertial sensor according to the fourth embodiment of the present invention.

FIG. 10 is a front-view cross-sectional diagram of the inertial sensor according to the fifth embodiment of the present invention.

FIG. 11 is a front-view cross-sectional diagram of the inertial sensor according to the sixth embodiment of the present invention.

FIG. 12 is a front-view cross-sectional diagram of the inertial sensor according to the seventh embodiment of the present invention.

FIG. 13 is a top-view diagram of the inertial sensor according to the seventh embodiment of the present invention.

FIG. 14 is a top-view diagram of the inertial sensor according to the seventh embodiment of the present invention.

FIG. 15 is a front-view cross-sectional diagram of the inertial sensor according to the eighth embodiment of the present invention.

FIG. 16 is a top-view diagram of the inertial sensor according to the ninth embodiment of the present invention.

FIG. 17 is a front-view cross-sectional diagram of the inertial sensor according to the tenth embodiment of the present invention.

FIG. 18 is a front-view cross-sectional diagram of the inertial sensor according to the eleventh embodiment of the present invention.

FIG. 19 is a top-view diagram of the inertial sensor according to the twelfth embodiment of the present invention.

FIG. 20 is a front-view cross-sectional diagram of the inertial sensor according to the thirteenth embodiment of the present invention.

FIG. 21 is a front-view cross-sectional diagram of the inertial sensor according to the fourteenth embodiment of the present invention.

FIG. 22 is a front-view cross-sectional diagram of the inertial sensor according to the fifteenth embodiment of the present invention.

FIG. 23 is a front-view cross-sectional diagram of the inertial sensor according to the sixteenth embodiment of the present invention.

### DETAILED DESCRIPTION OF THE INVENTION

Inertial sensors mainly comprise accelerometers and gyroscopes. An accelerometer can be used to detect vibration, shock, and tilt, etc., whose sensitivity determines the market application of an inertial sensor. For example, accelerometers with high sensitivity are primarily applied to national defense and quake detection, as opposed to accelerometers with regular sensitivity, which are mostly applied to the auto and consumer markets. Eighty percent of the accelerometers are used in the auto market, where high-g accelerometers are applied to airbags and other safety control systems, and low-g accelerometers that are applied to electronic control stabilizers, antilock brake systems, electronic control suspension systems, electronic parking aid systems, auto alarming systems, and navigation systems, etc. In medical applications, inertial sensors are commonly adopted in patient-monitoring devices such as pacemakers and fall-down detectors. In the area of national defense, inertial sensors are commonly used in missile guidance systems and in smart bombs. In industrial applications, inertial sensors are frequently used in transportation tools and construction machinery. For transportation tools, inertial sensors are used for tilt detection, position monitoring, rotation control, and platform level maintaining, such as keeping high-speed trains smooth and steady. Furthermore, the inertial sensors also can be used for the monitoring of quakes and structures, for tilt detection, and for the monitoring of displacement and vibrations.

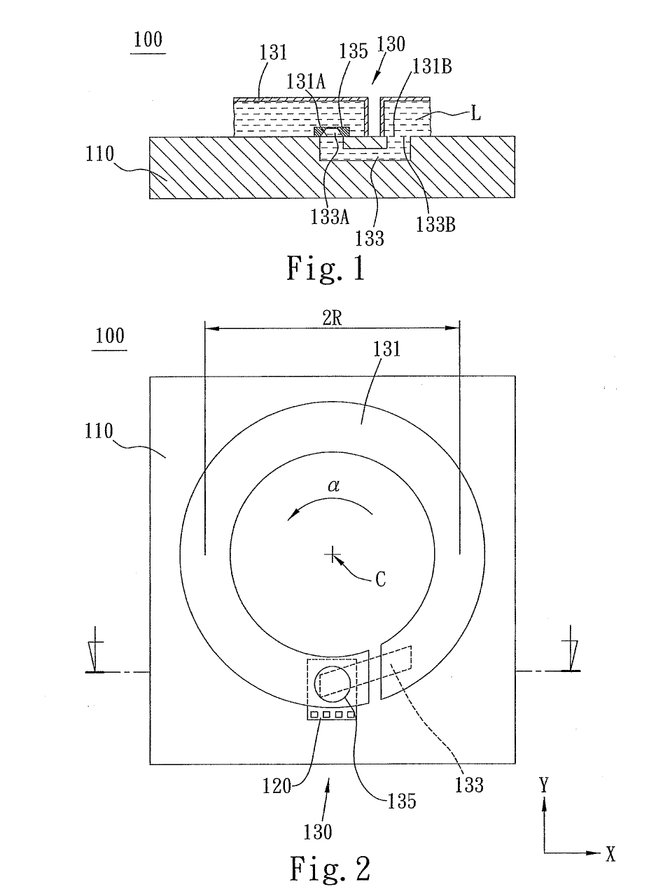

FIG. 1 and FIG. 2 respectively show a front view and a top view of an inertial sensor according to the first embodiment of the present invention. The inertial sensor 100 utilizes the pressure difference (pressure gradient) to measure the angular acceleration of a rotating object. The inertial sensor 100 comprises a substrate 110, a circuit 120 disposed on the substrate 110, a pressure device 130, and a fluid L. The pressure device 130 comprises: (1) an annular chamber 131 having a first end 131A and a second end 131B; (2) a channel 133 having a first end 133A and a second end 133B; and (3) a pressure meter 135 connected to the first end 131A of the annular chamber 131 and the first end 133A of the channel 133. The second end 133B of the channel 133 is connected to the second end 131B of the annular chamber 131; the pressure meter 135 is electrically connected to the circuit 120; and the fluid L is filled inside the annular chamber 131. Preferably, the fluid L can be water, oil, liquid crystal, or their mixtures.

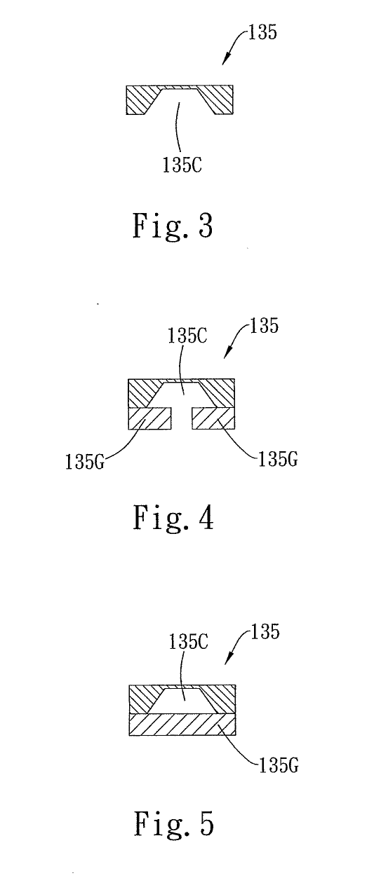

The structure of the pressure meter 135 can be like what is shown in FIGS. 3, 4, and 5. The pressure meter 135 in FIG. 3 can have a piezoresistive strain gauge, capacitive sensing, or similar sensors attached to its top end, and a chamber 135C formed in its bottom end, with the chamber being connected to the channel 133. The above-mentioned structure of the pressure meter 135 also can be like what is shown in FIGS. 4 and 5, with the structure being similar to that of the pressure meter 135 shown in FIG. 3. Nonetheless, the bottom of the pressure meter 135 shown in FIG. 4 has a glass substrate 135G, whose opening allows the chamber 135C to be connected to the channel 133. The bottom of the pressure meter 135 shown in FIG. 5 has a glass substrate 135G used to seal off the chamber 135C. The pressure value measured by the pressure meter 135 usually takes the chamber 135C pressure as the reference value. If the pressure above the pressure meter 135 is taken as a reference pressure, it becomes another embodiment for sensing the chamber 135C pressure. It becomes yet another embodiment, conventionally known as an absolute pressure meter, if the chamber 135C is closed and the reference pressure in the chamber 135C is not subject to the change of the environmental pressure.

A producing method for an inertial sensor 100 according to the present invention comprises the steps of: (1) providing a substrate 110; (2) forming a circuit 120 on the substrate 110; (3) forming a pressure device 130 on the substrate 110, wherein the channel 133 of the pressure device 130 can be formed within the substrate 110; the pressure meter 135 is electrically connected to the circuit 120 and also respectively connected to the first end 131A of the annular chamber 131 of the pressure device 130 and to the first end 133A of the channel 133;, and the second end 131B of the annular chamber 131 and the second end 133B of the channel 133 are connected to each other; (4) filling a fluid L into the annular chamber 131, wherein the fluid L can be water, oil, liquid crystal, or their mixtures. When the pressure meter 135 of the pressure device 130 detects a change in the pressure, it will transmit a signal to the circuit 120 to be calculated so as to obtain an angular acceleration of the rotating object.

An angular acceleration sensitivity is obtained through the pressure difference between the pressure value P of the pressure meter 135 and the reference pressure P₀ within the channel. The angular acceleration is determined by applying the formula (1) below:

α=P/(2πdR²) (1)
wherein, d stands for the density of the fluid L;
   α stands for the angular acceleration; and
   R stands for the radius of the annular chamber.

For instance, when the fluid density equals to 1 g/cm³, the radius of the annular chamber equals to 5 mm, and the pressure value equals to 0.157 Nt/m², the angular acceleration will be 1 rad/s².

Preferably, the substrate can be a silicon wafer, an integrated circuit, a printed circuit board, a glass substrate, a plastic substrate, or a ceramic substrate.

Preferably, the pressure meter 135 can be a capacitive-type, a piezoelectric-type, or a piezoresistive-type pressure meter.

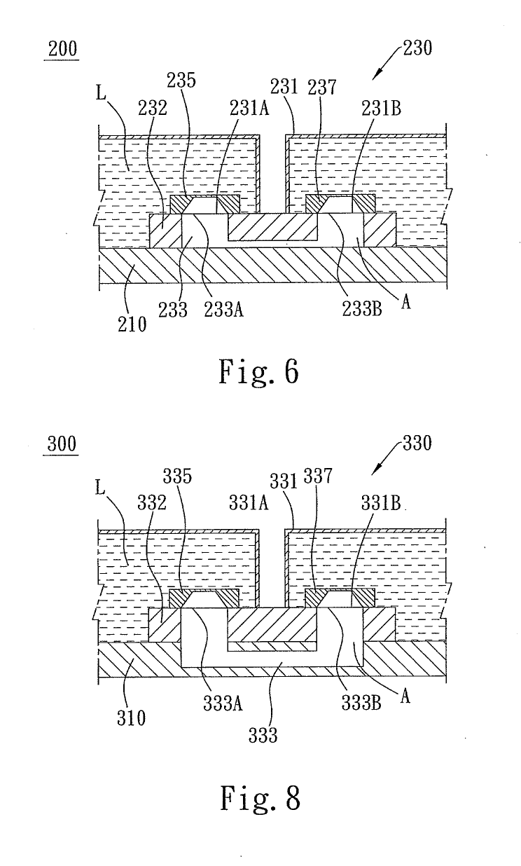

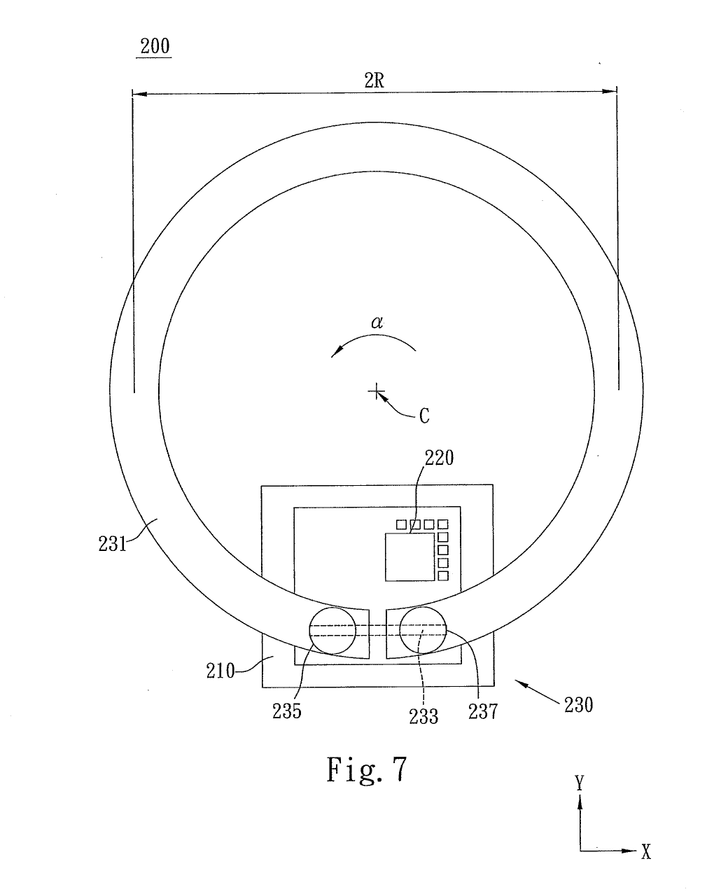

FIG. 6 and FIG. 7, respectively show a front-view cross sectional diagram and a top-view diagram of an inertial sensor 200 according to the second embodiment of the present invention. The inertial sensor 200 of the present invention utilizes the pressure difference (pressure gradient) to measure the angular acceleration of a rotating object. The inertial sensor 200 comprises a substrate 210, a circuit 220 disposed on the substrate 210, a pressure device 230, a fluid L, and a gas A. The pressure device 230 comprises: (1) an annular chamber 231 having a first end 231A and a second end 231B; (2) a base 232 having a channel 233 that has a first end 233A and a second end 233B, (3) a first pressure meter 235 connected respectively to the first end 231A of the annular chamber 231 and the first end 233A of the channel 233; and (4) a second pressure meter 237 connected respectively to the second end 231B of the annular chamber 231 and the second end 233B of the channel 233, wherein the first pressure meter 235 and the second pressure meter 237 are both electrically connected to the circuit 220. The fluid L is filled inside the annular chamber 231, and the gas A is filled inside the channel 233. When the first pressure meter 235 and the second pressure meter 237 of the pressure device 230 detect a change in the pressure, they will transmit a signal to the circuit 220 to be calculated so as to obtain an angular acceleration of the rotating object.

A producing method for an inertial sensor 200 according to the present invention comprises the steps of: (1) providing a substrate 210; (2) forming a circuit 220 on the substrate 210; (3) forming a pressure device 230 on the substrate 210, wherein the channel 233 of the pressure device 230 can be formed within the substrate 210, with the first pressure meter 235 being connected respectively to the first end 231A of the annular chamber 231 and the first end 233A of the channel 233; the second pressure meter 237 being connected respectively to the second end 231B of the annular chamber 231 and the second end 233B of the channel 233; and the first pressure meter 235 and the second pressure meter 237 being electrically connected to the circuit 220; (4) filling a fluid L into the annular chamber 231 and filling a gas A into the channel 233, wherein the fluid L can be water, oil, liquid crystal, or their mixtures, and the gas A can be air or be under vacuum condition.

An angular acceleration sensitivity of the inertial sensor is obtained through the pressure difference between the pressure value P₁ of the first pressure meter 235 and the pressure value P₂ of the second pressure meter 237. The angular acceleration is determined by applying the formula (2) below:

α=(P₂−P₁)/(2πdR²) (2)
wherein, d stands for the density of the fluid L;
   α stands for the angular acceleration; and
   R stands for the radius of the annular chamber.

For instance, when the fluid density equals to 1 g/cm³, the radius of the annular chamber equals to 5 mm, and the pressure difference equals to (P₂−P₁)=0.157 Nt/m², the angular acceleration a will amount to 1 rad/s².

Preferably, the first pressure meter 235 and the second pressure meter 237 can be a capacitive-type, a piezoelectric-type, and a piezoresistive-type pressure meter.

Preferably, the substrate can be a silicon wafer, an integrated circuit, a printed circuit board, a glass substrate, a plastic substrate, or a ceramic substrate.

The first embodiment and the second embodiment of the present invention are provided to measure an angular acceleration of a planar inertial sensor with high sensitivity, which offers a simple structure and an undemanding manufacturing process, reduces costs, and allows integration of different types of products.

FIG. 8 shows a front-view cross sectional diagram of the third embodiment of the inertial sensor 300 according to the present invention. The only difference between this embodiment and the second embodiment of the inertial sensor 200 is that the channel 333 can be extended into the substrate 310. The arrangement of the remaining elements of this embodiment is identical with that of the second embodiment.

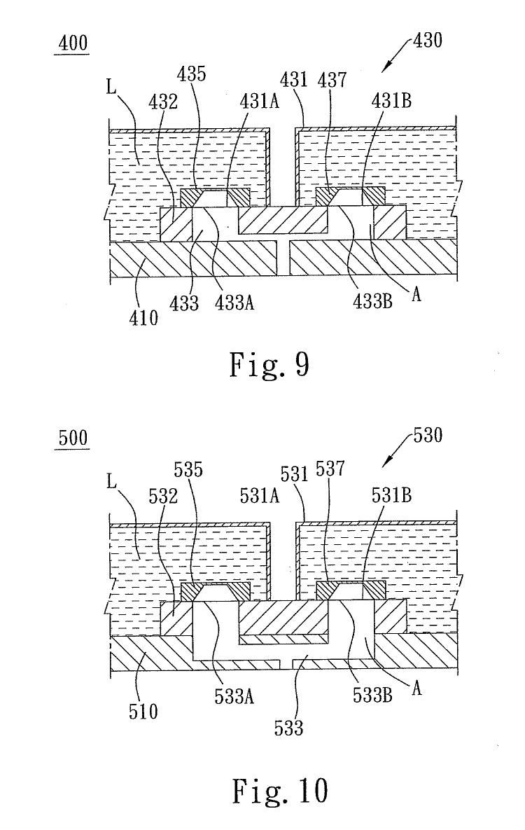

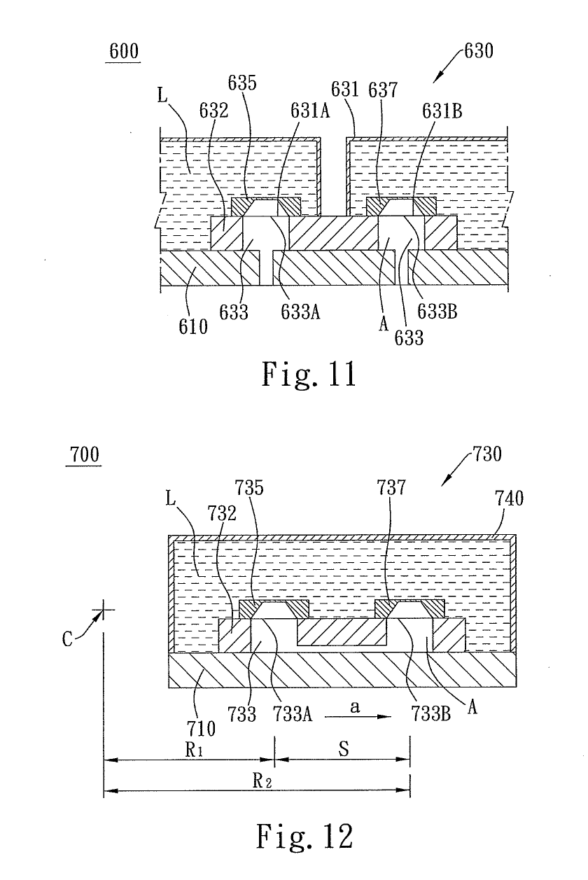

FIGS. 9, 10 and 11e show respectively the front-view cross-sectional diagrams of the inertial sensors 400, 500, and 600 according to the fourth, fifth, and sixth embodiments of the present invention. The only difference between the fourth, fifth, and sixth embodiments of the inertial sensor and the second embodiment of the inertial sensor 200 is that the channels 433, 533, 633 are extended into the substrate 410, 510, 610 through respective ways, so as to communicate with the outside world. The arrangement of the remaining elements in the fourth, fifth, and sixth embodiments is identical with that of the second embodiment.

FIG. 12 and FIG. 13 show respectively a front-view cross-sectional diagram and a top-view diagram of an inertial sensor 700 according to the seventh embodiment of the present invention. The inertial sensor 700 utilizes the pressure difference (pressure gradient) to measure the linear acceleration of a one-directional moving object. The inertial sensor 700 comprises a circuit 720, a pressure device 730, a housing 740, and a fluid L, wherein the housing 740 comprises a substrate 710 disposed on the bottom of the housing; the pressure device 730 comprises a base 732 having a channel 733 that has a first end 733A and a second end 733B; a first pressure meter 735 is connected to the first end 733A of the channel 733; and a second pressure meter 737 is connected to the second end 733B of the channel 733, with the first pressure meter 735 and the second pressure meter 737 both being electrically connected to the circuit 720. The housing 740 is disposed on the substrate for covering the circuit 720 and the pressure device 730. The fluid L is filled inside the housing 740, and the gas A is filled inside the channel 733. When the first pressure meter 735 and the second pressure meter 737 of the pressure device 730 detect a change in the pressure, they will transmit a signal to the circuit 720 to be calculated so as to obtain a linear acceleration of the one-directional moving object.

A producing method for an inertial sensor 700 according to the present invention comprises the steps of: providing a housing 740; forming a circuit 720 in the housing 740; and forming a pressure device 730 inside the housing 740, with a fluid L being filled into the housing 740. The housing 740 comprises a substrate 710 disposed on the bottom of the housing, and the channel 733 of the pressure device 730 can be formed within a base 732, with the first pressure meter 735 being connected to the first end 733A of the channel 733;, the second pressure meter 737 being connected to the second end 733B of the channel 733; and the first pressure meter 735 and the second pressure meter 737 being electrically connected to the circuit 720. The fluid L can be water, oil, liquid crystal, or their mixtures, and the channel 733 can be filled with gas A (e.g. air) or be under vacuum condition. Moreover, the channel can be sealed off or be communicated to an outside world.

Preferably, the first pressure meter 735 and the second pressure meter 737 can be a capacitive-type, a piezoelectric-type, or a piezoresistive-type pressure meter.

Preferably, the substrate can be a silicon wafer, an integrated circuit, a printed circuit board, a glass substrate, a plastic substrate, or a ceramic substrate.

A linear acceleration sensitivity of the inertial sensor is obtained through the pressure difference between the pressure value P₁ of the first pressure meter 735 and the pressure value P₂ of the second pressure meter 737. The acceleration is determined by applying the formula (3) below:

a=(P₂−P₁)/(d×S) (3)
wherein, d stands for the fluid density;
   a stands for the acceleration; and
   S stands for the distance from the center of the first pressure meter to the center of the second pressure meter.

For instance, when the fluid density equals to 1 g/cm³, the distance equals to 5 mm, and the pressure difference equals to 49 Nt/m², the acceleration will amount to 1 g (g stands for the acceleration of gravity on the surface of earth, which amounts to approximately 9.8 m/s²). The reason the channel 733 is filled with gas is because of the light density of the gas, and thus the density of gas A is neglected in the above calculation for the sake of easy understanding. The sole purpose of the channel 733 of the present invention is to provide the pressure meter with the same reference pressure, using gas in the channel for illustrative purposes only. As a matter of fact, according to the present invention, the channel can be under vacuum condition, or, the gas inside the channel can generally be referred to as fluids with lighter density. Therefore, even if the channel is filled with a different kind of fluid, that fluid can still create a pressure gradient under the influence of acceleration. In case the density of fluid L differs from that of fluid A, the formula above can still work provided that density d in the original formula is replaced by the density difference between fluid L and fluid A.

The centrifugal force resulting from the circular motion also leads to pressure gradients. The sensitivity of the inertial sensor towards the centrifugal force is obtained through the pressure difference between the pressure value P₁ of the first pressure meter 735 and the pressure value P₂ of the second pressure meter 737. The pressure difference is determined by applying the formula (4) below:

$$Δ P = {P}_{2} - {P}_{1} = d \times {ω}^{2} \times ( \frac{1}{2} {{R}_{2}}^{2} - \frac{1}{2} {{R}_{1}}^{2} ) \qquad ( 4 )$$

wherein, d stands for the fluid density;
   ω stands for the angular velocity;
   R₁ stands for the distance between the rotation center C and the center of the first pressure meter 735; and
   R₂ stands for the distance between the rotation center C and the center of the second pressure meter 737.

Generally speaking, the effect of the centrifugal force can be neglected if the rotation speed is not so fast.

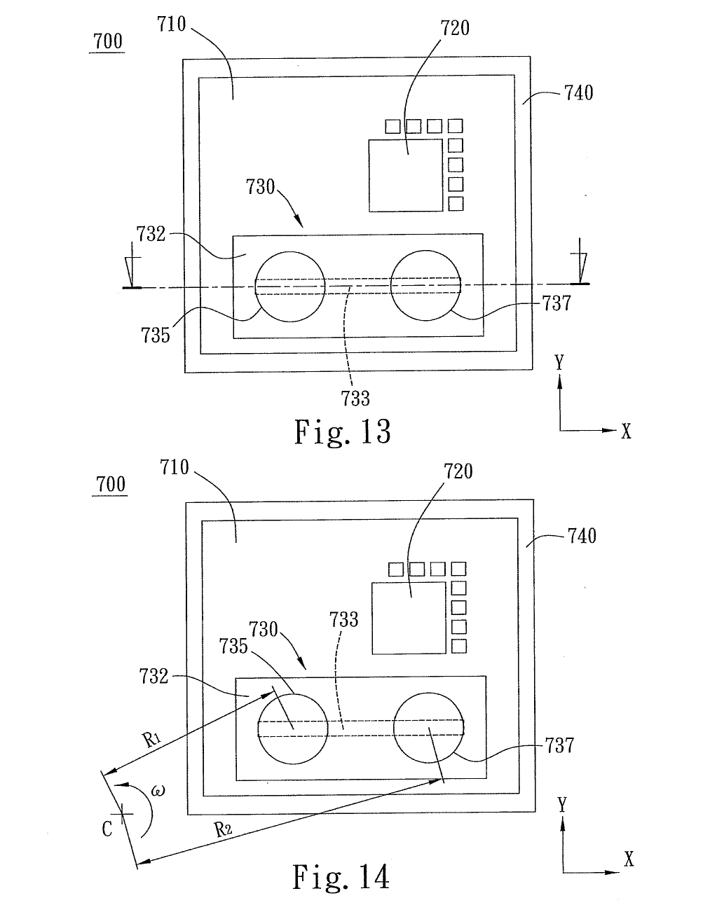

According to FIG. 14, the formula (4) remains applicable even if the rotation center C is non-collinear with the first pressure meter 735 and the second pressure meter 737.

FIG. 15 shows a front-view cross-sectional diagram of an inertial sensor 800 according to the eighth embodiment of the present invention. The only difference between this embodiment and the inertial sensor 700 of the seventh embodiment is that the channel 833 can be extended into the substrate 810.The arrangement of the remaining elements of this embodiment is identical with that of the seventh embodiment.

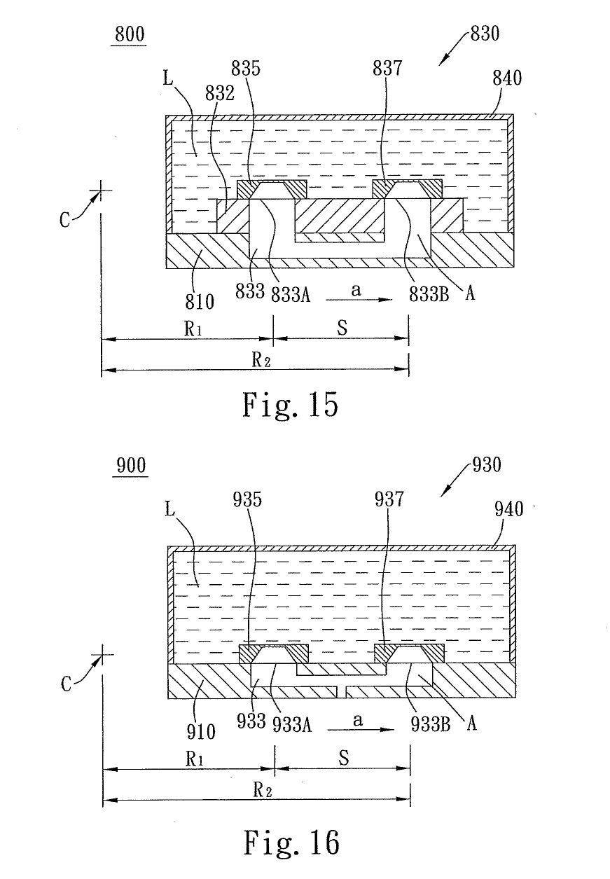

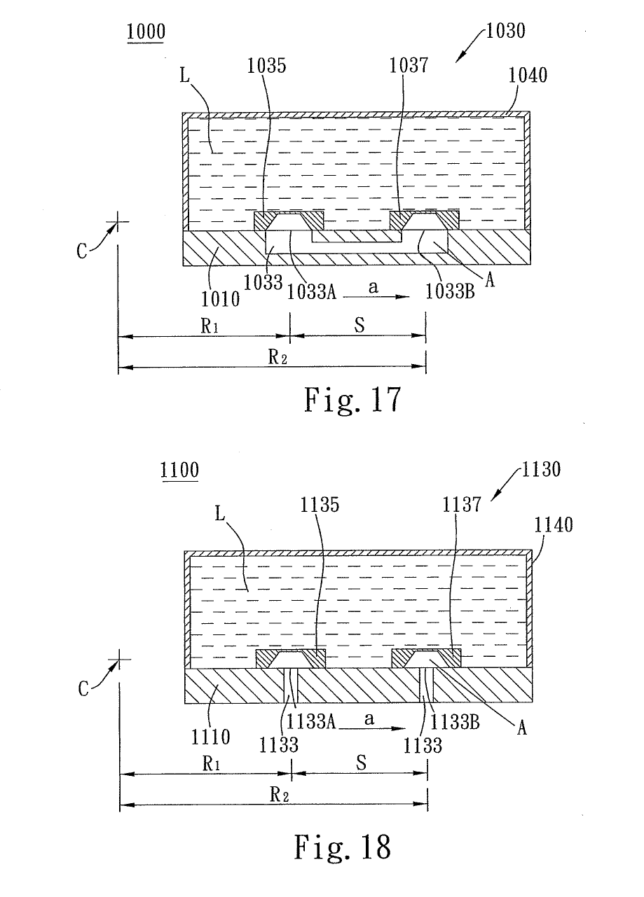

FIGS. 16, 17 and 18 show the front-view cross-sectional diagrams of the inertial sensor 900, 1000, and 1100 according to the ninth, tenth, and eleventh embodiments of the present invention. The only difference between these three embodiments and the seventh and eighth embodiments is that there are no base elements in these three embodiments. Besides, except for the fact that the channels 933, 1033, 1133 in these three embodiments are extended into the substrates 910, 1010, 1110 through respective ways so as to communicate with the outside world, the remaining elements of the three embodiments are the same as those of the seventh embodiment.

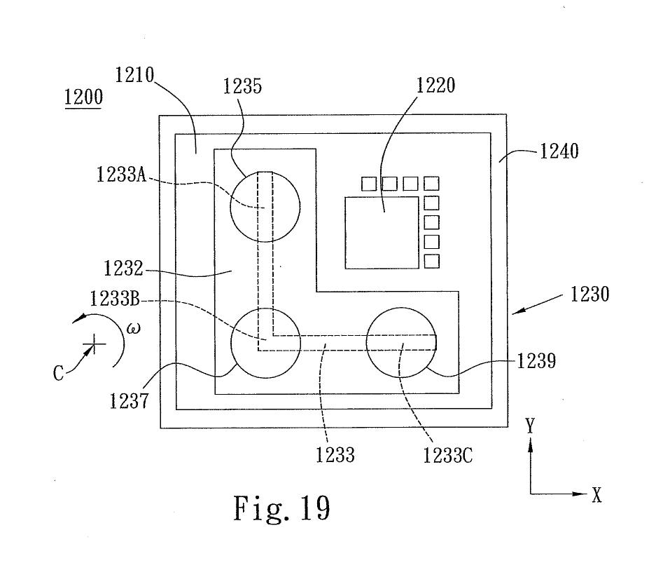

FIG. 19, shows a top-view diagram of an inertial sensor 1200 according to the twelfth embodiment of the present invention. The inertial sensor 1200 utilizes the pressure difference (pressure gradient) to measure the x directional acceleration and the y directional acceleration when an object moves along any direction in the X-Y plane. The inertial sensor 1200 comprises a substrate 1210, a circuit 1220 formed on the substrate 1210, a pressure device 1230, a housing 1240, a fluid L, and a gas A. The pressure device 1230 comprises: (1) a base 1232 having an L-shaped channel 1233 that has a first end 1233A, a second end 1233B, and a third end 1233C; (2) a first pressure meter 1235 connected to the first end 1233A of the L-shape channel 1233; (3) a second pressure meter 1237 connected to the second end 1233B of the

L-shaped channel 1233; and (4) a third pressure meter 1239 connected to the third end 1233C of the L-shaped channel 1233, wherein the first pressure meter 1235, the second pressure meter 1237, and the third pressure meter 1239 are all electrically connected to the circuit 1220. Besides, the housing 1240 is disposed on the substrate 1210 for covering the circuit 1220 and the pressure device 1230; the fluid L is filled inside the housing 1240; and the gas A is filled inside the channel 1233 as well. When the first pressure meter 1235, the second pressure meter 1237, and the third pressure meter 1239 of the pressure device 1230 detect a change in the pressure, they will transmit a signal to the circuit 1220 to be calculated so as to obtain the x directional acceleration and the y directional acceleration of a moving object along the X-Y direction.

The L-shaped base and the L-shaped channel are provided herein for illustrative purposes only. As a matter of fact, the outline of the base has no bearing on the function of the base, and the sole purpose of the gas channel is to provide a reference pressure to be shared among the pressure meters. The channel can also be connected to the outside world or be communicated to each other via the outside world. The information of the sensed acceleration along the X-Y direction can be obtained provided that the three pressure meters are disposed in a triangle formation (i.e., non-collinear).

A producing method for an inertial sensor 1200 of the present invention comprises the steps of: (1) providing a substrate 1210; (2) forming a circuit 1220 on the substrate 1210; (3) forming a pressure device 1230 on the substrate 1210, wherein the L-shaped channel 1233 of the pressure device 1230 can be formed within the L-shaped base 1232, with the first pressure meter 1235 being connected to the first end 1233A of the L-shaped channel 1233; the second pressure meter 1237 being connected to the second end 1233B of the L-shaped channel 1233; the third pressure meter 1239 being connected to the third end 1233C of the L-shaped channel 1233; and the first pressure meter 1235, the second pressure meter 1237, and the third pressure meter 1239 being all electrically connected to the circuit 1220; (4) filling the fluid L into the chamber (not shown), and filling the gas A into the channel 1233. The fluid L can be water, oil, liquid crystal, or their mixtures, and the gas A can be air or be under vacuum condition. The channel can be sealed off or be communicated to the outside world.

Preferably, the first pressure meter 1235, the second pressure meter 1237, and the third pressure meter 1239 can be a capacitive-type, a piezoelectric-type, or a piezoresistive-type pressure meter.

Preferably, the substrate can be a silicon wafer, an integrated circuit, a printed circuit board, a glass substrate, a plastic substrate, or a ceramic substrate.

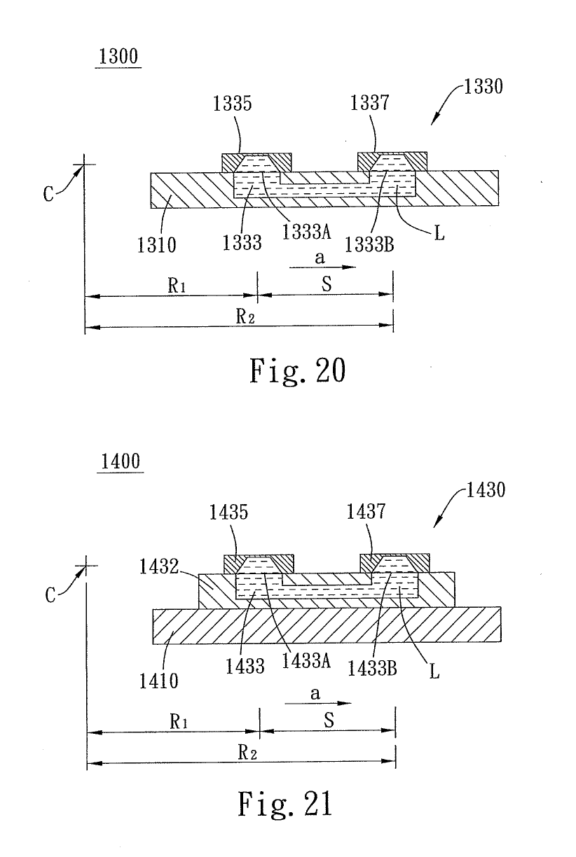

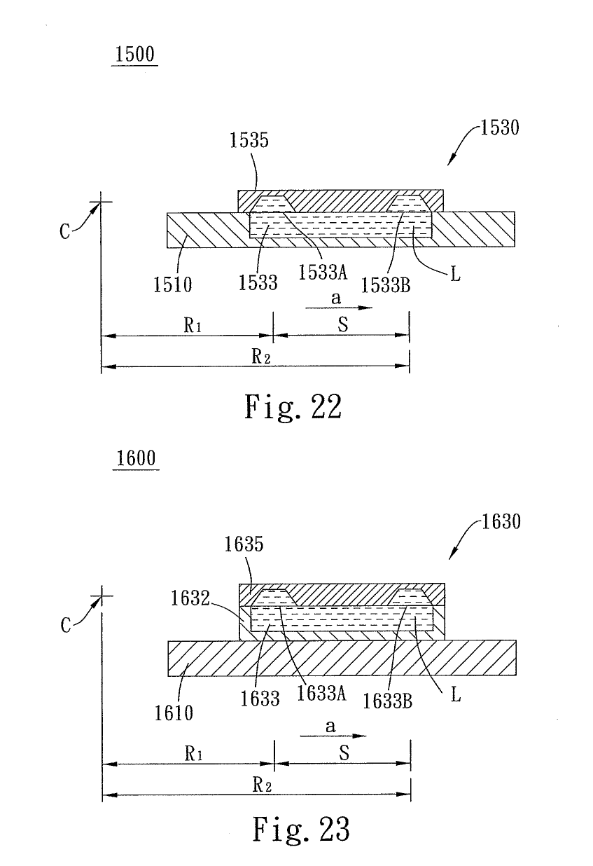

FIG. 20-FIG. 23 show the inertial sensors 1300, 1400, 1500, and 1600 according to the thirteenth, fourteenth, fifteenth, and sixteenth embodiments of the present invention. The principle and formula applied to the seventh embodiment are the same as those applied to the thirteenth, fourteenth, fifteenth, and sixteenth embodiments, the only difference being that the channels 1333, 1433, 1533 and 1633 are taken as housings for filling the fluid L, so as to take the outside pressure A as the reference pressure and to simplify the structures of the invention. Since the formation of the fluid's inner pressure gradient has nothing to do with the shape of the housing, the design of the channels 1333, 1433, 1533 and 1633 will suffice provided that it allows free communication of the fluid L.

Therefore, the present invention offers the following advantages:
1. The planar design largely simplifies the structure, with almost no moving parts contained therein.
2. Taking advantage of the fluid pressure to enhance the sensitivity.
3. Heating is not required; little energy is consumed; fluid flow is barely needed; and the invention is very responsive.
4. The planar structure meets the modem PCB based SIP manufacturing requirements. Alternatively, the planar structure can also have multiple pressure meters incorporated in one chip, so as to make it a 2-axe structure with almost no moving parts contained therein.
5. Basically, the inertial mass used for measurement is equivalent to the product of pressure meter sensing area, distance between the pressure meters, and density of the filling fluid, through which high sensitivity can be easily attained.
6. The present invention accommodates a capacitive pressure sensor, which has greater capacitance than that of a conventional comb electrode.
7. For the desirable incompressible fluid, the creation and the change of the pressure gradient do not have to go with the fluid flow. The system as such can be very responsive.

To sum up, the present invention utilizes a micro-structure manufacturing method to produce the planar inertial sensor with high sensitivity, so as to reduce the size of the inertial sensor and to expand the market application of the product. Besides, given the simple structure of the inertial sensor, the processing costs can be largely reduced during mass production. Moreover, the inertial sensor according to the present invention utilizes the pressure difference (pressure gradient) to measure the acceleration or angular acceleration of a moving or rotating object, further allowing multi-axis measurements based on mutual integration. The present invention meets all the requirements of patentability and, therefore, the application is filed pursuant to the Patent Law.

The above mentioned preferred embodiments of the present invention are not meant to limit the scope of the present invention. The description of the present invention should be understood by those skilled in the art. Moreover, any changes or modifications or the equivalent thereof that can be made without departing from spirit of the present invention should be protected by the following claims.

What is claimed is:

1. An inertial sensor, comprising:
a substrate;
a circuit;
a pressure device, comprising:
an annular chamber having a first end and a second end;
a channel having a first end and a second end, with the second end being connected to the second end of the annular chamber;
a pressure meter connected respectively to the first end of the annular chamber and the first end of the channel, wherein the pressure meter is electrically connected to the circuit; and
a fluid filling the annular chamber.

2. The inertial sensor according to claim 1, wherein the substrate comprises a silicon wafer, an integrated circuit, a printed circuit board, a glass substrate, a plastic substrate, or a ceramic substrate.

3. The inertial sensor according to claim 1, wherein the pressure meter comprises a capacitive-type a piezoelectric-type, or a piezoresistive-type pressure meter.

4. The inertial sensor according to claim 1, wherein the fluid is liquid.

5. The inertial sensor according to claim 4, wherein the liquid comprises water, oil, liquid crystal, or their mixtures.

6. The inertial sensor according to claim 1, wherein the circuit is disposed on the substrate.

7. The inertial sensor according to claim 1, wherein the circuit is disposed outside of the inertial sensor.

8. The inertial sensor according to claim 1, further comprising an angular acceleration sensitivity obtained through the pressure value measured by the pressure meter, whereby the angular acceleration is determined by applying the formula below:
α=P/(2πdR²); wherein
P stands for the pressure value measured by the pressure meter;
d stands for the fluid density;
α stands for the angular acceleration; and
R stands for the radius of the annular chamber.

9. An inertial sensor, comprising:
a substrate;
a circuit;
a pressure device, comprising:
an annular chamber having a first end and a second end;
a base;
a first pressure meter connected to the first end of the annular chamber and electrically connected to the circuit;
a second pressure meter connected to the second end of the annular chamber and electrically connected to the circuit; and
a fluid filling the annular chamber.

10. The inertial sensor according to claim 9, wherein the base comprises a channel having a first end and a second end, with the first end of the channel being connected to a chamber of the first pressure meter and the second end of the channel being connected to a chamber of the second pressure meter.

11. The inertial sensor according to claim 9, wherein the substrate comprises a silicon wafer, an integrated circuit, a printed circuit board, a glass substrate, a plastic substrate, or a ceramic substrate.

12. The inertial sensor according to claim 10, wherein the channel is disposed on the substrate.

13. The inertial sensor according to claim 10, wherein the channel is extended into the substrate.

14. The inertial sensor according to claim 10, wherein the channel is filled with air.

15. The inertial sensor according to claim 10, wherein the channel is under vacuum condition.

16. The inertial sensor according to claim 9, wherein each of the first pressure meter and the second pressure meter comprises a capacitive-type, a piezoelectric-type, or a piezoresistive-type pressure meter.

17. The inertial sensor according to claim 9, wherein the circuit is disposed on the substrate.

18. The inertial sensor according to claim 9, wherein the circuit is disposed outside of the inertial sensor.

19. The inertial sensor according to claim 9, wherein the fluid is liquid.

20. The inertial sensor according to claim 19, wherein the liquid comprises water, oil, liquid crystal, or their mixtures.

21. The inertial sensor according to claim 9, further comprising an angular acceleration sensitivity obtained through the pressure difference between the first pressure meter and the second pressure meter, whereby the angular acceleration is determined by applying the formula below:
α=(P₂−P₁)/(2πdR²); wherein
P₁ stands for the pressure value measured by the first pressure meter;
P₂ stands for the pressure value measured by the second pressure meter;
d stands for the the fluid density;
α stands for the angular acceleration; and
R stands for the radius of the annular chamber.

22. An inertial sensor, comprising:
a circuit;
a pressure device, comprising:
a base;
a first pressure meter disposed on the base, with the first pressure meter being electrically connected to the circuit;
a second pressure meter disposed on the base, with the second pressure meter being electrically connected to the circuit;
a housing having the pressure device contained therein; and
a fluid filling the housing.

23. The inertial sensor according to claim 22, wherein the base comprises a channel having a first end and a second end, with the first end of the channel being connected to a chamber of the first pressure meter and the second end of the channel being connected to a chamber of the second pressure meter.

24. The inertial sensor according to claim 22, wherein a substrate is disposed on the bottom of the housing.

25. The inertial sensor according to claim 22, wherein the housing comprises an upper lid and a substrate.

26. The inertial sensor according to claim 23, wherein the channel further comprises a third end non-collinear with the first end and the second end.

27. The inertial sensor according to claim 26, wherein the pressure device further comprises a third pressure meter connected to the third end of the channel and electrically connected to the circuit.

28. The inertial sensor according to claim 24, wherein the substrate comprises a silicon wafer, an integrated circuit, a printed circuit board, a glass substrate, a plastic substrate, or a ceramic substrate.

29. The inertial sensor according to claim 25, wherein the substrate comprises a silicon wafer, an integrated circuit, a printed circuit board, a glass substrate, a plastic substrate, or a ceramic substrate.

30. The inertial sensor according to claim 23, wherein the channel is disposed on the substrate.

31. The inertial sensor according to claim 23, wherein the channel is extended into the substrate.

32. The inertial sensor according to claim 23, wherein the channel is filled with air.

33. The inertial sensor according to claim 23, wherein the channel is under vacuum condition.

34. The inertial sensor according to claim 22, wherein each of the first pressure meter and the second pressure meter comprises a capacitive-type, a piezoelectric-type, or a piezoresistive-type pressure meter.

35. The inertial sensor according to claim 27, wherein each of the first pressure meter, the second pressure meter, and the third pressure meter comprises a capacitive-type, a piezoelectric-type, or a piezoresistive-type pressure meter.

36. The inertial sensor according to claim 22, wherein the fluid is liquid.

37. The inertial sensor according to claim 36, wherein the liquid is water, oil, liquid crystal, or their mixtures.

38. The inertial sensor according to claim 22, further comprising a linear 125 acceleration sensitivity obtained through the pressure difference between the first pressure meter and the second pressure meter, whereby the acceleration is determined by applying the formula below:
a=(P₂−P₁)/(d×S); wherein
P₁ stands for the pressure value of the first pressure meter;
P₂ stands for the pressure value of the second pressure meter;
d stands for the fluid density;
a stands for the acceleration; and
S stands for the distance between the center of the first pressure meter and the center of the second pressure meter.

39. The inertial sensor according to claim 22, further comprising an angular velocity sensitivity obtained through the pressure difference between the first pressure meter and the second pressure meter, whereby the pressure difference is determined by applying the formula below:
$$Δ P = {P}_{2} - {P}_{1} = d \times {ω}^{2} \times ( \frac{1}{2} {{R}_{2}}^{2} - \frac{1}{2} {{R}_{1}}^{2} ) ; wherein$$
P₁ stands for the pressure value of the first pressure meter;
P₂ stands for the pressure value of the second pressure meter;
d stands for the fluid density;
ω stands for the angular velocity;
R₁ stands for the distance between the rotating center and the center of the first pressure meter; and
R₂ stands for the distance between the rotating center and the center of the second pressure meter.

40. A producing method for an inertial sensor, comprising the steps of:
providing a housing;
forming a circuit;
forming a pressure device within the housing, and
filling a fluid into the housing.

41. The producing method for the inertial sensor according to claim 40, wherein a substrate is disposed on the bottom of the housing.

42. The producing method for the inertial sensor according to claim 40, wherein the circuit is disposed inside the housing.

43. The producing method for the inertial sensor according to claim 40, wherein the circuit is disposed outside the housing.

44. The producing method for the inertial sensor according to claim 41, wherein the circuit and the pressure device are disposed on the substrate.

45. The producing method for the inertial sensor according to claim 41, wherein the substrate comprises a silicon wafer, an integrated circuit, a printed circuit board, a glass substrate, a plastic substrate, or a ceramic substrate.

46. The producing method for the inertial sensor according to claim 40, wherein the pressure device comprises:
a base containing a channel, which has a first end and a second end;
a first pressure meter connected to the first end of the channel and electrically connected to the circuit; and
a second pressure meter connected to the second end of the channel and electrically connected to the circuit.

47. The producing method for the inertial sensor according to claim 46, wherein the channel further comprises a third end and takes an L-shaped form on the planar surface.

48. The producing method for the inertial sensor according to claim 47, wherein the pressure device further comprises a third pressure meter connected to the third end of the channel and electrically connected to the circuit.

49. The producing method for the inertial sensor according to claim 46, wherein the channel is disposed on the substrate.

50. The producing method for the inertial sensor according to claim 46, wherein the channel is extended into the substrate.

51. The producing method for the inertial sensor according to claim 46, wherein the channel is filled with air.

52. The producing method for the inertial sensor according to claim 46, wherein the channel is under vacuum condition.

53. The producing method for the inertial sensor according to claim 46, wherein the first pressure meter and the second pressure meter comprises a capacitive-type, a piezoelectric-type, or a piezoresistive-type pressure meter.

54. The producing method for the inertial sensor according to claim 48, wherein the first pressure meter, the second pressure meter, and the third pressure meter comprises a capacitive-type, a piezoelectric-type, or a piezoresistive-type pressure meter.

55. The inertial sensor according to claim 40, wherein the fluid filled into the housing is a liquid.

56. The producing method for the inertial sensor according to claim 55, wherein the liquid comprises water, oil, liquid crystal, or their mixtures.

57. An inertial sensor, comprising:
a circuit;
a pressure device, comprising:
a base containing a channel, which has a first end and a second end;
a first pressure meter connected to the first end of the channel, and electrically connected to the circuit; and
a second pressure meter connected to the second end of the channel and electrically connected to the circuit; and
a fluid filling the channel.

58. The inertial sensor according to claim 57, wherein each of the first pressure meter and the second pressure meter comprises a capacitive-type, a piezoelectric-type, or a piezoresistive-type pressure meter.

59. The inertial sensor according to claim 57, wherein a substrate is disposed on the bottom of the pressure device.

60. The inertial sensor according to claim 57, wherein the substrate comprises a silicon wafer, an integrated circuit, a printed circuit board, a glass substrate, a plastic substrate, or a ceramic substrate.

61. The inertial sensor according to claim 57, wherein the fluid filled into the channel is a liquid.

62. The inertial sensor according to claim 61, wherein the liquid comprises water, oil, liquid crystal, or their mixtures.
